(19) United States
(12) Patent Application Publication
(10) Pub. No.: US 2023/0322604 A1
(43) Pub. Date: Oct. 12, 2023

(54) THERMAL INSULATION APPARATUS AND CRUCIBLE PRODUCTION DEVICE

(71) Applicant: BAOSHAN LONGI SILICON MATERIALS CO., LTD., Baoshan, Yunnan (CN)

(72) Inventors: Linkui YANG, Baoshan, Yunnan (CN); Aijun LIU, Baoshan, Yunnan (CN); Xinjun CHEN, Baoshan, Yunnan (CN); Shuzhen DENG, Baoshan, Yunnan (CN); Guoman LI, Baoshan, Yunnan (CN); Hankai ZHAO, Baoshan, Yunnan (CN); Shaojun LI, Baoshan, Yunnan (CN); Jielong SHAO, Baoshan, Yunnan (CN)

(21) Appl. No.: 18/021,351

(22) PCT Filed: Sep. 1, 2021
(86) PCT No.: PCT/CN2021/116061

§ 371 Date: Feb. 14, 2023

(30) Foreign Application Priority Data
Sep. 18, 2020 (CN) 202022058432.1

(51) Int. Cl. C03B 19/02; C03B 19/09

(52) U.S. Cl. CPC C03B 19/02; C03B 19/09

(57) ABSTRACT

The present disclosure provides a thermal insulation apparatus and a crucible production device. The thermal insulation apparatus is configured for supporting a mold, and includes: a housing, a first flange, a second flange and a plurality of reinforcing members, and the housing, the first flange and the second flange are coaxially arranged. An inner wall of the housing is enclosed to form an accommodating cavity, and the accommodating cavity is configured for accommodating the mold; a water-cooling cavity is enclosed between the inner wall and an outer wall of the housing; the first flange is connected to a top portion of the housing, so as to fix an upper edge of the mold to the top portion of the housing; the second flange is connected to a bottom portion of the housing; and the plurality of reinforcing members are arranged between the bottom portion of housing and second flange.

### CROSS-REFERENCE TO RELEVANT APPLICATIONS

The present disclosure claims the priority of the Chinese patent application filed on September 18^{th}, 2020 before the CNIPA, China National Intellectual Property Administration with the application number of 202022058432.1 and the title of ″THERMAL INSULATION APPARATUS AND CRUCIBLE PRODUCTION DEVICE″, which is incorporated herein in its entirety by reference.

### TECHNICAL FIELD

The present disclosure relates to the technical field of crucible production devices and, more particularly, to a thermal insulation apparatus and a crucible production device.

### BACKGROUND

With the technical development of photovoltaic industry, a size of a silicon wafer is becoming bigger and bigger, and a size of a quartz crucible, which is used as a necessary auxiliary material for preparing crystalline silicon, is also increased accordingly. In a preparation process of the quartz crucible, a thermal insulation apparatus usually needs to be used cooperatively, and the thermal insulation apparatus may be configured for thermally isolating, cooling and supporting a crucible mold.

In the prior art, the thermal insulation apparatus may include a housing, a water-cooling cavity is enclosed between an inner wall and an outer wall of the housing, the mold is placed in the cavity enclosed by the inner wall, and the housing is configured for supporting the mold.

In the preparation process of the crucible, the thermal insulation apparatus needs to bear weights of the mold and the crucible, since the mold is usually made of a metal material and has a large weight, a load-bearing of the housing is large, and with the increase of the size of the crucible, an existing thermal insulation apparatus is prone to cracking and leaking water due to the large load-bearing, which shortens a service life of the thermal insulation apparatus.

### SUMMARY

The first set of metal rods and the second set of metal rods are both evenly distributed around the axis of the housing.

Optionally, the thermal insulation apparatus further includes: a plurality of first strengthening members; and

the plurality of first strengthening members are arranged in the water-cooling cavity, each first strengthening member is respectively abutted with an outer wall at a side surface and an outer wall at the bottom portion of the housing, and one reinforcing member is correspondingly provided with one first strengthening member.

Optionally, the thermal insulation apparatus further includes: a plurality of second strengthening members; and

the plurality of second strengthening members are arranged in the water-cooling cavity, each second strengthening member is respectively abutted with the outer wall at the side surface of the housing and the first flange, and one first strengthening member is symmetrically provided with one second strengthening member.

Optionally, the thermal insulation apparatus further includes: an annular supporting member and a vacuum pipeline, and the vacuum pipeline and the annular supporting member are both coaxially arranged with the housing;
the annular supporting member and the vacuum pipeline are arranged between the bottom portion of the housing and the second flange, the vacuum pipeline penetrates through the bottom portion of the housing and the second flange, and the annular supporting member is sleeved outside the vacuum pipeline; and
the reinforcing member is fixedly connected to the annular supporting member.

Optionally, the thermal insulation apparatus further includes: at least one water supply pipe and at least one water return pipe;
the at least one water supply pipe and the at least one water return pipe are arranged around the vacuum pipeline, and arranged between the vacuum pipeline and the annular supporting member; and
the at least one water supply pipe is respectively connected to the water-cooling cavity to supply water to the water-cooling cavity, and the at least one water return pipe is respectively connected to the water-cooling cavity to discharge the water in the water-cooling cavity to an exterior of the thermal insulation apparatus.

Optionally, the upper edge of the mold is provided with a plurality of connecting holes;
a plurality of first through holes and a plurality of second through holes are formed in the first flange, the first through holes and the second through holes are alternately arranged, and numbers of the first through holes, the second through holes and the connecting holes are the same; and
one connecting hole corresponds to one first through hole or one second through hole.

In a second aspect, the present disclosure further discloses a crucible production device, which includes the thermal insulation apparatus above.

The present disclosure includes the following advantages:

in embodiments of the present disclosure, the inner wall of the housing is enclosed to form the accommodating cavity, so that the accommodating cavity may be configured for accommodating the mold, the water-cooling cavity is enclosed between the inner wall and the outer wall of the housing, so that the thermal insulation apparatus may thermally isolate and cool the mold, the first flange is fixedly connected to the top portion of the housing, so as to fix the upper edge of the mold to the top portion of the housing, so that the thermal insulation apparatus may be configured for supporting the mold, and since the second flange is connected to the bottom portion of the housing, and the plurality of reinforcing members are arranged between the bottom portion of the housing and the second flange, a load-bearing capacity of the housing of the thermal insulation apparatus can be increased, thus preventing a phenomenon of frequent cracking and water leakage of the housing of the thermal insulation apparatus due to incapability of supporting the mold, and prolonging a service life of the thermal insulation apparatus.

### BRIEF DESCRIPTION OF THE DRAWINGS

The drawings described herein are configured for providing further understanding for the present disclosure, and constitute a part of the present disclosure. Exemplary embodiments of the present disclosure and the descriptions thereof are configured for explaining the present disclosure, and do not constitute any inappropriate limitation to the present disclosure. In the drawings:

FIG. 1 is a first schematic structural diagram of a thermal insulation apparatus of the present disclosure;

FIG. 2 is a second schematic structural diagram of the thermal insulation apparatus of the present disclosure;

FIG. 3 is a schematic structural diagram of a bottom portion of the thermal insulation apparatus of the present disclosure;

FIG. 4 is a sectional view of an A-A direction in FIG. 3 of the present disclosure;

FIG. 5 is a sectional view of a B-B direction in FIG. 3 of the present disclosure;

FIG. 6 is a first sectional view of the thermal insulation apparatus of the present disclosure; and

FIG. 7 is a second sectional view of the thermal insulation apparatus of the present disclosure.

### DETAILED DESCRIPTION OF THE EMBODIMENTS

In order to make the above objects, features and advantages of the present disclosure clearer and more understandable, the present disclosure is further described in detail hereinafter with reference to the drawings and the specific embodiments.

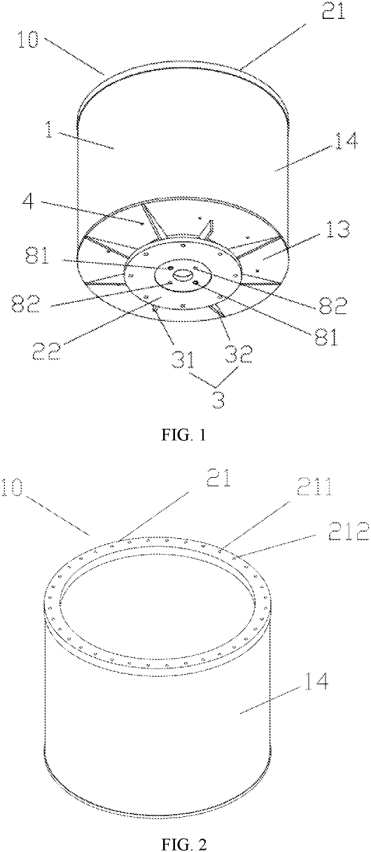

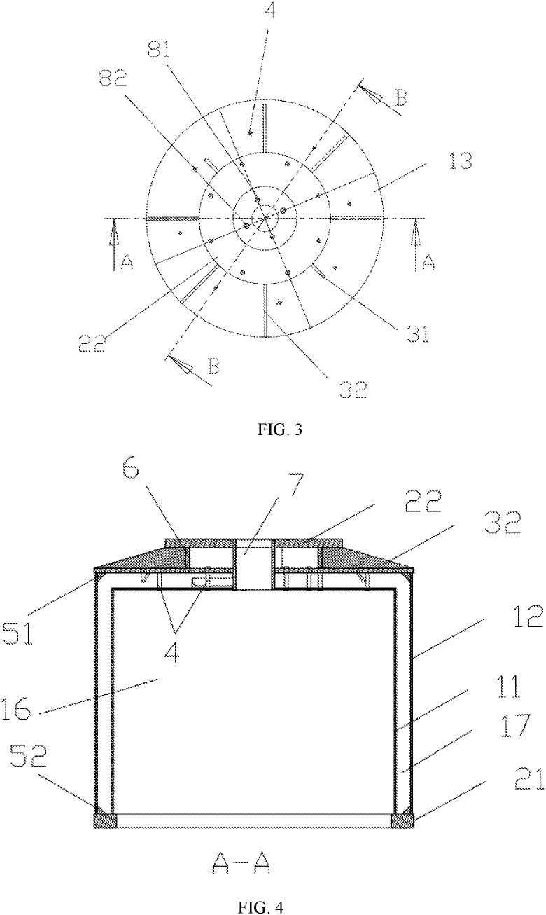

Referring to FIG. 1, FIG. 1 is a first schematic structural diagram of a thermal insulation apparatus of the present disclosure. Referring to FIG. 2, FIG. 2 is a second schematic structural diagram of the thermal insulation apparatus of the present disclosure. Referring to FIG. 3, FIG. 3 is a schematic structural diagram of a bottom portion of the thermal insulation apparatus of the present disclosure. Referring to FIG. 4, FIG. 4 is a sectional view of an A-A direction in FIG. 3 of the present disclosure. As shown in FIG. 1, FIG. 2, FIG. 3 and FIG. 4, the present disclosure provides a thermal insulation apparatus 10 configured for supporting a mold 90 (not shown in the drawings), the thermal insulation apparatus 10 may include: a housing 1, a first flange 21, a second flange 22 and a plurality of reinforcing members 3, and the housing 1, the first flange 21 and the second flange 22 may be coaxially arranged. An inner wall 11 of the housing 1 is enclosed to form an accommodating cavity 16, and the accommodating cavity 16 may be configured for accommodating the mold 90. A water-cooling cavity 17 may be enclosed between the inner wall 11 and an outer wall 12 of the housing 1. The first flange 21 may be fixedly connected to a top portion of the housing 1, so as to fix an upper edge of the mold 90 to the top portion of the housing 1. The second flange 22 may be connected to a bottom portion 13 of the housing 1. The plurality of reinforcing members 3 may be arranged between the bottom portion 13 of the housing 1 and the second flange 22.

In embodiments of the present disclosure, the inner wall 11 of the housing 1 is enclosed to form the accommodating cavity 16, so that the accommodating cavity 16 may be configured for accommodating the mold 90. The water-cooling cavity 17 may further be enclosed between the inner wall 11 and the outer wall 12 of the housing 1, so that the thermal insulation apparatus 10 may thermally isolate and cool the mold 90. The first flange 21 is fixedly connected to the top portion of the housing 1, so as to fix the upper edge of the mold 90 to the top portion of the housing 1, so that the thermal insulation apparatus 10 may be configured for supporting the mold 90. Since the second flange 22 is connected to the bottom portion 13 of the housing 1, and the plurality of reinforcing members 3 are arranged between the bottom portion 13 of the housing 1 and the second flange 22, a load-bearing capacity of the housing 1 of the thermal insulation apparatus 10 can be increased, thus preventing a phenomenon of frequent cracking and water leakage of the housing 1 of the thermal insulation apparatus 10 due to incapability of supporting the mold 90, and prolonging a service life of the thermal insulation apparatus 10.

Optionally, the plurality of reinforcing members 3 are evenly distributed around an axis of the housing 1. In practical application, the plurality of reinforcing members 3 are both evenly distributed around the axis of the housing 1, which can increase an overall strength of the housing 1, thus preventing a phenomenon of a high local strength or a low local strength of the housing 1, and then preventing a phenomenon of cracking and water leakage of a low-strength part of the housing 1.

As shown in FIG. 3, the plurality of reinforcing members 3 may include two symmetrically arranged first reinforcing members 31, and the plurality of reinforcing members except the first reinforcing members 31 are second reinforcing members 32. Specifically, a cross-sectional shape of the first reinforcing members 31 may be a trapezoid, and a cross-sectional shape of the second reinforcing members 32 may be a rectangle. In practical application, the two symmetrically arranged first reinforcing members 31 may be forked by a forklift to mount the thermal insulation apparatus 10, which is convenient for mounting and positioning of the thermal insulation apparatus 10.

In an embodiment of the present disclosure, the bottom portion 13 of the housing 1 may further be provided with a plurality of metal rods 4, and the plurality of metal rods 4 may be arranged between the inner wall 11 and the outer wall 12. A plurality of first openings 131 (not shown in the drawings) are formed in an inner wall 11 of the bottom portion 13 of the housing 1, a plurality of second openings 132 (not shown in the drawings) are formed in an outer wall 12 at the bottom portion 13 of the housing 1, and each second opening 132 may correspond to one first opening 131. One end of the metal rod 4 may be embedded in one first opening 131 and welded with the inner wall 11 of the bottom portion 13 of the housing 1, and the other end of the metal rod 4 may be embedded in one second opening arranged 132 correspondingly and welded with the outer wall 12 of the bottom portion 13 of the housing 1.

In the embodiment of the present disclosure, corresponding first opening 131 and second opening 132 are formed in the inner wall 11 and the outer wall 12 at the bottom portion 13 of the housing 1, and welded with the metal rod 4 correspondingly. In this way, the metal rod 4 penetrates through the inner wall 11 and the outer wall 12 of the bottom portion 13 of the housing 1, which can increase a strength of the bottom portion 13 of the housing 1, thus preventing the thermal insulation apparatus 10 from expanding and deforming by heating.

Optionally, the plurality of metal rods 4 are divided into a first set of metal rods 4 and a second set of metal rods 4, and distances from the first set of metal rods 4 to a center of the housing 1 and distances from the second set of metal rods 4 to the center of the housing 1 may be different. The first set of metal rods 4 and the second set of metal rods 4 may be both evenly distributed around the axis of the housing 1. In practical application, the metal rods 4 are divided into two sets, and each set of metal rods 4 is evenly distributed around the axis of the housing 1, which can increase an overall strength of the bottom portion 13 of the housing 1. Specifically, one set of metal rods 4 may further be evenly arranged at a position of one-third circle of a diameter of the bottom portion 13 of the housing 1, and one set of metal rods 4 may further be evenly arranged at a position of two-thirds circle of the diameter of the bottom portion 13 of the housing 1. For example, 8 metal rods 4 may be evenly arranged at the position of one-third circle of the diameter of the bottom portion 13 of the housing 1, and 8 metal rods 4 may be evenly arranged at the position of two-thirds circle of the diameter of the bottom portion 13 of the housing 1. The metal rods 4 at the position of one-third circle of the diameter of the bottom portion 13 of the housing 1 and the metal rods 4 at the position of two-thirds circle of the diameter of the bottom portion 13 of the housing 1 may be staggered, so as to make strengths at all positions of the bottom portion 13 of the housing 1 more uniform.

In practical application, the second flange 22 may be a flange plate, and the bearing force capacity of the bottom portion 13 of the housing 1 can be increased by increasing a size of the second flange 22.

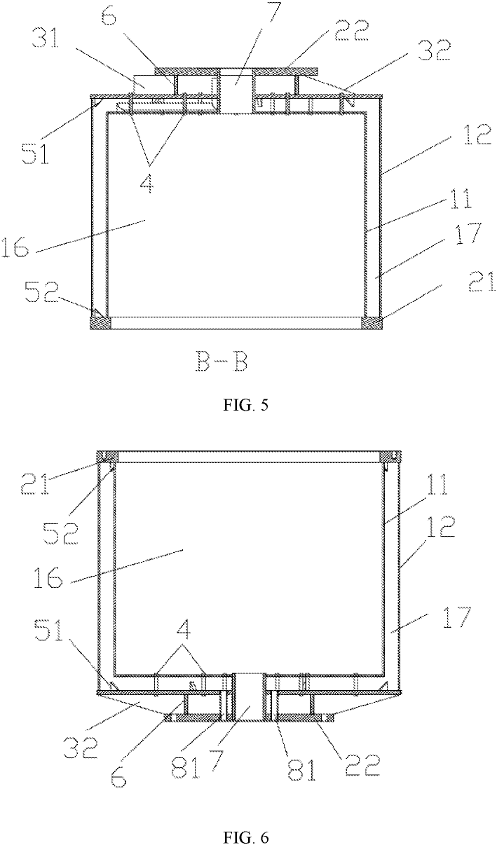

Referring to FIG. 5, FIG. 5 is a sectional view of a B-B direction in FIG. 3 of the present disclosure. As shown in FIG. 4 and FIG. 5, the thermal insulation apparatus 10 may further include a plurality of first strengthening members 51. The plurality of first strengthening members 51 may be arranged in the water-cooling cavity 17, each first strengthening member 51 may be respectively abutted with an outer wall 12 at a side surface 14 and an outer wall 12 at the bottom portion 13 of the housing 1, and one reinforcing member 3 may be correspondingly provided with one first strengthening member 51.

In the embodiment of the present disclosure, the plurality of first strengthening members 51 may be arranged in the water-cooling cavity 17, and each first strengthening member 51 is respectively abutted with the outer wall 12 at the side surface 14 and the outer wall 12 at the bottom portion 13 of the housing 1. In this way, the first strengthening member 51 is arranged at a joint of the outer wall 12 at the side surface 14 and the outer wall 12 at the bottom portion 13 of the housing 1, which can increase a strength of the joint of the side surface 14 and the bottom portion 13 of the housing 1, and then reinforce the outer wall 12 of the thermal insulation apparatus 10, thus preventing the outer wall 12 from cracking.

Optionally, the thermal insulation apparatus 10 may further include a plurality of second strengthening members 52. The plurality of second strengthening members 52 may be arranged in the water-cooling cavity 17, each second strengthening member 52 may be respectively abutted with the outer wall 12 at the side surface 14 of the housing 1 and the first flange 21, and one first strengthening member 51 may be symmetrically provided with one second strengthening member 52.

In practical application, the plurality of second strengthening members 52 may be arranged in the water-cooling cavity 17, and each second strengthening member 52 is respectively abutted with the outer wall 12 at the side surface 14 of the housing 1 and the first flange 21. In this way, the second strengthening member 52 is arranged at a joint of the outer wall 12 at the side surface 14 of the housing 1 and the first flange 21, which can increase a strength of the joint of the side surface 14 of the housing 1 and the first flange 21, and then reinforce the outer wall 12 of the thermal insulation apparatus 10, thus preventing the outer wall 12 from cracking.

Optionally, the thermal insulation apparatus 10 may further include: an annular supporting member 6 and a vacuum pipeline 7. The vacuum pipeline 7 and the annular supporting member 6 may be both coaxially arranged with the housing 1. The annular supporting member 6 and the vacuum pipeline 7 may be arranged between the bottom portion 13 of the housing 1 and the second flange 22, the vacuum pipeline 7 may penetrate through the bottom portion 13 of the housing 1 and the second flange 22, and the annular supporting member 6 may be sleeved outside the vacuum pipeline 7. The reinforcing member 3 may be fixedly connected to the annular supporting member 6.

In the embodiment of the present disclosure, the annular supporting member 6 is arranged between the bottom portion 13 of the housing 1 and the second flange 22, and the reinforcing member 3 is fixedly connected to the annular supporting member 6, which may prevent a phenomenon of cracking of the second flange 22 due to concentrated stress. Moreover, the vacuum pipeline 7 is arranged between the bottom portion 13 of the housing 1 and the second flange 22, and the vacuum pipeline 7 penetrates through the bottom portion 13 of the housing 1 and the second flange 22, so that air between the thermal insulation apparatus 10 and the mold 90 may be pumped out through the vacuum pipeline 7 to form a vacuum environment, thus preventing bubbles from being formed in a crucible to affect a texture of the crucible. The vacuum pipeline 7 and the annular supporting member 6 are both coaxially arranged with the housing 1, which is convenient for assembly of the vacuum pipeline 7, the annular supporting member 6 and the housing 1, and can improve a structural stability of the thermal insulation apparatus 10.

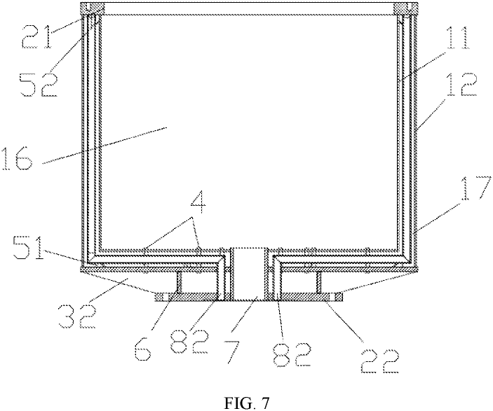

Referring to FIG. 6, FIG. 6 is a first sectional view of the thermal insulation apparatus of the present disclosure, and Referring to FIG. 7, FIG. 7 is a second sectional view of the thermal insulation apparatus of the present disclosure. As shown in FIG. 6 and FIG. 7, the thermal insulation apparatus 10 may further include at least one water supply pipe 81 and at least one water return pipe 82. The at least one water supply pipe 81 and the at least one water return pipe 82 may be arranged around the vacuum pipeline 7, and arranged between the vacuum pipeline 7 and the annular supporting member 6. The at least one water supply pipe 81 may be respectively connected to the water-cooling cavity 17 to supply water to the water-cooling cavity 17, and the at least one water return pipe 82 may be respectively connected to the water-cooling cavity 17 to discharge the water in the water-cooling cavity 17 to an exterior of the thermal insulation apparatus 10.

In the embodiment of the present disclosure, the thermal insulation apparatus 10 includes the at least one water supply pipe 81 and the at least one water return pipe 82, and the water supply pipe 81 is configured for supplying water to the water-cooling cavity 17 and the water return pipe 82 is configured for discharging the water in the water-cooling cavity 17, which can effectively improve a heat dissipation capacity of the thermal insulation apparatus 10.

Specifically, in order to improve the heat dissipation capacity of the thermal insulation apparatus 10, one water supply pipe 81 with a larger diameter may be disposed, or at least two water supply pipes 81 with a smaller diameter may be disposed. The at least two water supply pipes 81 may be arranged around the vacuum pipeline 7, and each water supply pipe 81 may sequentially penetrate through the second flange 22 and the outer wall 12 at the bottom portion 13 of the housing 1, so as to deliver cooling water to the water-cooling cavity 17. FIG. 6 only shows a situation that two water supply pipes 81 are symmetrically arranged on two sides of the vacuum pipeline 7, and other situations may be achieved by referring to FIG. 6. Similarly, in order to improve the heat dissipation capacity of the thermal insulation apparatus 10, one water return pipe 82 with a larger diameter may be disposed, or at least two water return pipes 82 with a smaller diameter may be disposed. One ends of the at least two water return pipes 82 may be arranged around the vacuum pipeline 7, wherein one end of each water return pipe 82 penetrates through the second flange 22 and the outer wall 12 of the bottom portion 13 of the housing 1, and the other ends of the at least two water return pipes are close to the top portion of the housing 1, so as to pump out the cooling water in the water-cooling cavity 17 from the top portion of the housing 1. FIG. 7 only shows a situation that two water return pipes 82 are symmetrically arranged on two sides of the vacuum pipeline 7, and other situations may be achieved by referring to FIG. 7.

In an embodiment of the present disclosure, the upper edge of the mold 90 may be provided with a plurality of connecting holes 91 (not shown in the drawings). A plurality of first through holes 211 and a plurality of second through holes 212 may be arranged in the first flange 21, the first through holes 211 and the second through holes 212 may be alternately arranged, and numbers of the first through holes 211, the second through holes 212 and the connecting holes 91 may be the same. One connecting hole 91 may correspond to one first through hole 211 or one second through hole 212.

In the embodiment of the present disclosure, in a situation that the upper edge of the mold 90 is fixed to the top portion of the housing 1 of the thermal insulation apparatus 10, the first through holes 211 in the first flange 21 may be aligned and fixed with the connecting holes 91 in the upper edge of the mold 90, or the second through holes 212 in the first flange 21 may be aligned and fixed with the connecting holes 91 in the upper edge of the mold 90, so that the first flange 21 may be provided with two sets of fixing through holes, and the second through holes 212 may be activated when the first through holes 211 are failed, thus reducing a scrapping loss of the thermal insulation apparatus 10 caused by the failure of the fixing through holes in the first flange 21.

The thermal insulation apparatus provided by the embodiments of the present disclosure at least includes the following advantages:

in the embodiments of the present disclosure, the inner wall of the housing is enclosed to form the accommodating cavity, so that the accommodating cavity may be configured for accommodating the mold, the water-cooling cavity is enclosed between the inner wall and the outer wall of the housing, so that the thermal insulation apparatus may thermally isolate and cool the mold, the first flange is fixedly connected to the top portion of the housing, so as to fix the upper edge of the mold to the top portion of the housing, so that the thermal insulation apparatus may be configured for supporting the mold, and since the second flange is connected to the bottom portion of the housing, and the plurality of reinforcing members are arranged between the bottom portion of the housing and the second flange, a load-bearing capacity of the housing of the thermal insulation apparatus can be increased, thus preventing a phenomenon of frequent cracking and water leakage of the housing of the thermal insulation apparatus due to incapability of supporting the mold, and prolonging a service life of the thermal insulation apparatus.

In a second aspect, the present disclosure further provides a crucible production device, which may include the thermal insulation apparatus 10 above.

The crucible production device provided by the embodiment of the present disclosure at least includes the following advantages:

in embodiments of the present disclosure, the inner wall of the housing is enclosed to form the accommodating cavity, so that the accommodating cavity may be configured for accommodating the mold, the water-cooling cavity is enclosed between the inner wall and the outer wall of the housing, so that the thermal insulation apparatus may thermally isolate and cool the mold, the first flange is fixedly connected to the top portion of the housing, so as to fix the upper edge of the mold to the top portion of the housing, so that the thermal insulation apparatus may be configured for supporting the mold, and since the second flange is connected to the bottom portion of the housing, and the plurality of reinforcing members are arranged between the bottom portion of the housing and the second flange, a load-bearing capacity of the housing of the thermal insulation apparatus can be increased, thus preventing a phenomenon of frequent cracking and water leakage of the housing of the thermal insulation apparatus due to incapability of supporting the mold, and prolonging a service life of the thermal insulation apparatus.

Finally, it should also be noted that relational terms herein such as first and second, etc., are used merely to distinguish one entity or operation from another entity or operation, and do not necessarily require or imply there is any such relationship or order between these entities or operations. Furthermore, the terms “including”, “comprising” or any variations thereof are intended to embrace a non-exclusive inclusion, such that a process, a method, an article, or a terminal device including a series of elements, includes not only those elements but also includes other elements not expressly listed, or also includes elements inherent to such process, method, article, or terminal device. In the absence of further limitation, an element defined by the phrase “including a ...” does not exclude the presence of the same element in the process, method, article, or terminal device.

The thermal insulation apparatus and the crucible production device provided by the present disclosure are described in detail above, the specific examples are used herein to explain the principle and embodiments of the present disclosure, and the descriptions of the embodiments above are only used to help understanding the method and the core concept of the present disclosure. Meanwhile, for those of ordinary skills in the art, variations may be made on the specific embodiments and the application scope according to the idea of the present disclosure. To sum up, the contents of the specification should not be understood as limiting the present disclosure.

1. A thermal insulation apparatus configured for supporting a crucible mold, comprising: a housing, a first flange, a second flange and a plurality of reinforcing members, the housing, the first flange and the second flange being coaxially arranged;
wherein an inner wall of the housing is enclosed to form an accommodating cavity, and the accommodating cavity is configured for accommodating the crucible mold;
a water-cooling cavity is enclosed between the inner wall and an outer wall of the housing;
the first flange is fixedly connected to a top portion of the housing, so as to match with an upper edge of the crucible mold;
the second flange is connected to a bottom portion of the housing; and
the plurality of reinforcing members are arranged between the bottom portion of the housing and the second flange.

2. The thermal insulation apparatus according to claim 1, wherein the plurality of reinforcing members are evenly distributed around an axis of the housing.

3. The thermal insulation apparatus according to claim 1, wherein the bottom portion of the housing is further provided with a plurality of metal rods, and the plurality of metal rods are arranged between the inner wall and the outer wall;
a plurality of first openings are formed in an inner wall of the bottom portion of the housing, a plurality of second openings are formed in an outer wall of the bottom portion of the housing, and each second opening corresponds to one first opening; and
one end of the metal rod is embedded in one first opening and welded with the inner wall of the bottom portion of the housing, and the other end of the metal rod is embedded in one second opening arranged correspondingly and welded with the outer wall of the bottom portion of the housing.

4. The thermal insulation apparatus according to claim 3, wherein the plurality of metal rods are divided into a first set of metal rods and a second set of metal rods, and distances from the first set of metal rods to a center of the housing and distances from the second set of metal rods to the center of the housing are different; and
the first set of metal rods and the second set of metal rods are both evenly distributed around the axis of the housing.

5. The thermal insulation apparatus according to claim 1, wherein the thermal insulation apparatus further comprises: a plurality of first strengthening members; and
the plurality of first strengthening members are arranged in the water-cooling cavity, each first strengthening member is respectively abutted with an outer wall at a side surface and an outer wall at the bottom portion of the housing, and one reinforcing member is correspondingly provided with one first strengthening member.

6. The thermal insulation apparatus according to claim 5, wherein the thermal insulation apparatus further comprises: a plurality of second strengthening members; and
the plurality of second strengthening members are arranged in the water-cooling cavity, each second strengthening member is respectively abutted with the outer wall at the side surface of the housing and the first flange, and one first strengthening member is symmetrically provided with one second strengthening member.

7. The thermal insulation apparatus according to claim 1, wherein the thermal insulation apparatus further comprises: an annular supporting member and a vacuum pipeline, and the vacuum pipeline and the annular supporting member are both coaxially arranged with the housing;
the annular supporting member and the vacuum pipeline are arranged between the bottom portion of the housing and the second flange, the vacuum pipeline penetrates through the bottom portion of the housing and the second flange, and the annular supporting member is sleeved outside the vacuum pipeline; and
the reinforcing member is fixedly connected to the annular supporting member.

8. The thermal insulation apparatus according to claim 7, wherein the thermal insulation apparatus further comprises: at least one water supply pipe and at least one water return pipe;
the at least one water supply pipe and the at least one water return pipe are arranged around the vacuum pipeline, and arranged between the vacuum pipeline and the annular supporting member; and
the at least one water supply pipe is respectively connected to the water-cooling cavity to supply water to the water-cooling cavity, and the at least one water return pipe is respectively connected to the water-cooling cavity to discharge the water in the water-cooling cavity to an exterior of the thermal insulation apparatus.

9. The thermal insulation apparatus according to claim 1, wherein the upper edge of the crucible mold is provided with a plurality of connecting holes;
a plurality of first through holes and a plurality of second through holes are formed in the first flange, the first through holes and the second through holes are alternately arranged, and numbers of the first through holes, the second through holes and the connecting holes are the same; and
one connecting hole corresponds to one first through hole or one second through hole.

10. A crucible production device, comprising the thermal insulation apparatus according to claim 1.

11. The crucible production device according to claim 10, wherein the plurality of reinforcing members are evenly distributed around an axis of the housing.

12. The crucible production device according to claim 10, wherein the bottom portion of the housing is further provided with a plurality of metal rods, and the plurality of metal rods are arranged between the inner wall and the outer wall;
a plurality of first openings are formed in an inner wall of the bottom portion of the housing, a plurality of second openings are formed in an outer wall of the bottom portion of the housing, and each second opening corresponds to one first opening; and
one end of the metal rod is embedded in one first opening and welded with the inner wall of the bottom portion of the housing, and the other end of the metal rod is embedded in one second opening arranged correspondingly and welded with the outer wall of the bottom portion of the housing.

13. The crucible production device according to claim 12, wherein the plurality of metal rods are divided into a first set of metal rods and a second set of metal rods, and distances from the first set of metal rods to a center of the housing and distances from the second set of metal rods to the center of the housing are different; and
the first set of metal rods and the second set of metal rods are both evenly distributed around the axis of the housing.

14. The crucible production device according to claim 10, wherein the thermal insulation apparatus further comprises: a plurality of first strengthening members; and
the plurality of first strengthening members are arranged in the water-cooling cavity, each first strengthening member is respectively abutted with an outer wall at a side surface and an outer wall at the bottom portion of the housing, and one reinforcing member is correspondingly provided with one first strengthening member.

15. The crucible production device according to claim 14, wherein the thermal insulation apparatus further comprises: a plurality of second strengthening members; and
the plurality of second strengthening members are arranged in the water-cooling cavity, each second strengthening member is respectively abutted with the outer wall at the side surface of the housing and the first flange, and one first strengthening member is symmetrically provided with one second strengthening member.

16. The crucible production device according to claim 10, wherein the thermal insulation apparatus further comprises: an annular supporting member and a vacuum pipeline, and the vacuum pipeline and the annular supporting member are both coaxially arranged with the housing;
the annular supporting member and the vacuum pipeline are arranged between the bottom portion of the housing and the second flange, the vacuum pipeline penetrates through the bottom portion of the housing and the second flange, and the annular supporting member is sleeved outside the vacuum pipeline; and
the reinforcing member is fixedly connected to the annular supporting member.

17. The crucible production device according to claim 16, wherein the thermal insulation apparatus further comprises: at least one water supply pipe and at least one water return pipe;
the at least one water supply pipe and the at least one water return pipe are arranged around the vacuum pipeline, and arranged between the vacuum pipeline and the annular supporting member; and
the at least one water supply pipe is respectively connected to the water-cooling cavity to supply water to the water-cooling cavity, and the at least one water return pipe is respectively connected to the water-cooling cavity to discharge the water in the water-cooling cavity to an exterior of the thermal insulation apparatus.

18. The crucible production device according to claim 10, wherein the upper edge of the crucible mold is provided with a plurality of connecting holes;
a plurality of first through holes and a plurality of second through holes are formed in the first flange, the first through holes and the second through holes are alternately arranged, and numbers of the first through holes, the second through holes and the connecting holes are the same; and
one connecting hole corresponds to one first through hole or one second through hole.
